(19) United States
(12) Patent Application Publication
(10) Pub. No.: US 2014/0098504 A1
(43) Pub. Date: Apr. 10, 2014

(54) ELECTROPLATING METHOD FOR PRINTED CIRCUIT BOARD

(71) Applicant: YMT CO., LTD., Incheon (KR)

(72) Inventors: Sung-Wook CHUN, Incheon (KR); Jung Il Kim, Incheon (KR); Young Kuk Kim, Seoul (KR)

(73) Assignee: YMT CO., LTD., Incheon (KR)

(21) Appl. No.: 13/678,973

(22) Filed: Nov. 16, 2012

(30) Foreign Application Priority Data
Oct. 4, 2012 (KR) 10-2012-0110012

(51) Int. Cl. H05K 3/18; H05K 1/09

(52) U.S. Cl. CPC H05K 3/188; H05K 1/092
USPC 361/760; 205/255; 205/181; 205/125

(57) ABSTRACT

Disclosed is an electroplating method for printed circuit board. The method includes: providing a printed circuit board including a circuit pattern, a pad part on which components are mounted, a terminal part for electrical connection to an external device, and a connector part; masking the portion of the printed circuit board other than the terminal part and the connector part; dipping the printed circuit board in a nickel-tungsten alloy plating solution including a water-soluble nickel compound, a water-soluble tungsten compound, a complexing agent, and a ductility improver; forming a nickel-tungsten alloy plated layer on each of the exposed portions of the terminal part and the connector part by direct-current (DC) electroplating; and forming a gold-containing plated layer on the nickel-tungsten alloy plated layer by DC electroplating.

### BACKGROUND OF THE INVENTION

1. Field of the Invention

The present invention relates to an electroplating method for a printed circuit board to form a deposit layer with good wear and corrosion resistance.

2. Description of the Related Art

Electronic components, such as memory modules and battery terminals, undergo repeated attachment and detachment during use and are thus required to have good wear, scratch and corrosion resistance. According to the prior art, hard gold electroplating is performed to form gold plated layers with high hardness after nickel electroplating. The hard gold electroplating is a codeposition process using a mixture of gold and small amounts of cobalt, nickel, etc. FIG. 1 shows a photograph of a typical memory module product. However, exposure of a nickel plated layer of the memory module product to the outside by wear or scratches changes the electrical properties of the memory module product and results in an increased danger of corrosion. To protect the nickel plated layer from exposure, hard gold plating is performed to cover the nickel plated layer. The hard gold-plated layer has a thickness of at least 0.76 μm, often a thickness about 3.0 μm depending on the kind of products. The thick gold plated layer is a cause of an increase in manufacturing cost. Particularly, along with the recent steep rise in gold price, a heavy economic burden is imposed on hard gold plating.

Hard gold plating processes are widely known technology in the art. For example, Korean Unexamined Patent Publication No. 2011-0006589 proposes a gold plating method which uses a hard gold plating solution containing an organic acid conductive salt, a nitro group-containing compound, carboxylic acid, etc. with gold and a cobalt source salt. The use of the hard gold plating solution facilitates gold plating. Further, Korean Patent Registration No. 10-0819855 describes a method for manufacturing a printed circuit board through a combination of electroless nickel-gold plating and hard gold plating processes. Further, PCT International Publication No. WO 2010/024099 describes a composition of a hard gold plating solution capable of selective plating which comprises a soluble metal salt, a nitro group-containing aromatic compound, metal salts, such as cobalt, nickel and silver salts, and optionally an organic additive, such as polyethyleneimine.

Such processes for forming hard gold plated layers on electroplated nickel layers have been used for many years and have mainly aimed at improving the physical properties (e.g., hardness and wear resistance) of gold plated layers. Not very much research has been conducted on nickel plated layers. In other words, research has concentrated on the improvement of the characteristics of overlying hard gold plated layers plated on underlying nickel plated layers, but little research has been conducted on the characteristics of underlying nickel plated layers. However, such direction of research does not provide satisfactory results in bringing about a reduction in the thickness of gold plated layers, making it impossible to expect cost reduction effects. Improvements in the properties of gold plated layers are also limited.

### SUMMARY OF THE INVENTION

According to an aspect of the present invention, there is provided a nickel-tungsten alloy plating solution including a water-soluble nickel compound, a water-soluble tungsten compound, a complexing agent, and a ductility improver.

According to another aspect of the present invention, there is provided a method for plating a printed circuit board, the method including; dipping a printed circuit board in an electroplating bath containing a nickel-tungsten alloy plating solution including a water-soluble nickel compound, a water-soluble tungsten compound, a complexing agent, and a ductility improver; applying an electric current between anode and cathode disposed in the electrodeposition bath to form a nickel-tungsten alloy plated layer on the surface of the printed circuit board; and forming a gold-containing plated layer on the nickel-tungsten alloy plated layer.

According to another aspect of the present invention, there is provided a method for plating a printed circuit board, the method including: providing a printed circuit board including a circuit pattern, a pad part on which components are mounted, a terminal part for electrical connection to an external device, and a connector part; masking the portion of the printed circuit board other than the terminal part and the connector part; dipping the printed circuit board in a nickel-tungsten alloy plating solution including a water-soluble nickel compound, a water-soluble tungsten compound, a complexing agent, and a ductility improver; forming a nickel-tungsten alloy plated layer on each of the exposed portions of the terminal part and the connector part by direct-current (DC) electroplating; and forming a gold-containing plated layer on the nickel-tungsten alloy plated layer by DC electroplating.

According to yet another aspect of the present invention, there is provided a printed circuit board plated by the described plating method.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 shows a photograph of a typical memory module product;

FIG. 2 is a process flow chart illustrating a method for forming a nickel-tungsten alloy plated layer and a gold-containing plated layer on a printed circuit board;

FIG. 3 shows transmission electron microscopy images of (a) a conventional electroplated nickel layer and (b) an electroplated nickel-tungsten alloy layer;

FIG. 4 shows scanning electron microscopy (SEM) images showing the surface structures of plated layers formed using a plating solution with or without a ductility improver; and

FIG. 5 schematically illustrates a process for plating a module product using a plating solution.

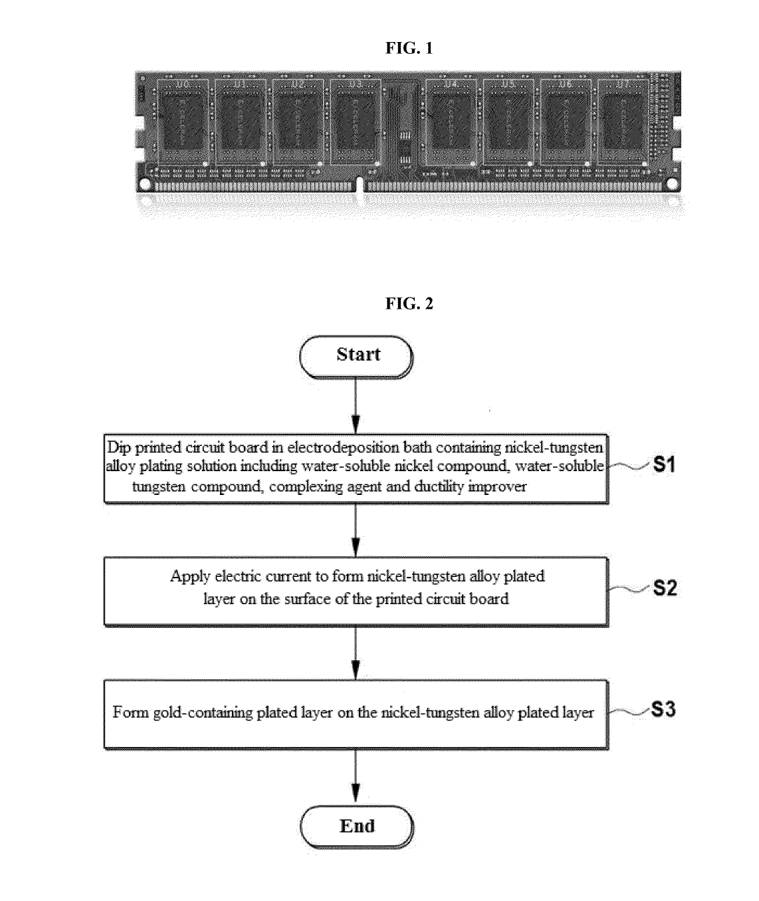

### DETAILED DESCRIPTION OF THE INVENTION

Embodiments of the present invention will now be described in more detail with reference to the accompanying drawings. These embodiments are provided so that this disclosure is thorough, and will fully convey the scope of the invention to those skilled in the art. Accordingly, the present invention may be embodied in many different forms and should not be construed as limited to the exemplary embodiments set forth herein. In the drawings, the dimensions, such as widths, lengths and thicknesses, of elements may be exaggerated for clarity. The same reference numerals denote the same elements throughout the drawings. The drawings are explained from an observer's point of view. It will be understood that when an element is referred to as being “on” another element, it can be directly on or directly on the other element, or one or more intervening elements may also be present there between.

As already described in the Background of the Invention, according to the prior art, hard gold electroplating using a gold plating solution containing small amounts of cobalt, nickel, etc. is performed on electroplated nickel layers of electronic components, such as memory modules, connectors and battery terminals, which undergo repeated attachment and detachment during use and are thus required to have good wear, scratch and corrosion resistance, to form gold plated layers with high hardness.

Hereinafter, such a hard gold electroplating method will be explained in more detail. First, a terminal part to be plated is pretreated by degreasing and microetching. The pretreated terminal part is dipped in a nickel electroplating solution at about 45 to 50° C. for 10 to 20 minutes and an direct-current (DC) having a current density of 0.5 to 3 ASD (A/dm²) is applied thereto to form an electroplated nickel layer having a thickness of about 3 to about 10 μm. Thereafter, a gold plating strike process is performed to form a thin gold plated layer on the electroplated nickel layer, after which the resulting structure is brought into contact with a hard gold plating solution to form a gold plated layer having a thickness of about 0.76 to about 3 μm. The reason why the lower limit of the thickness of the hard gold plated layer is set to 0.76 μm is that repeated attachment and detachment causes wear of the gold plated layer to expose the nickel layer, resulting in changes in electrical properties. That is, the thick gold plated layer is required to protect the plated layer against wear.

As described above, according to the conventional hard gold electroplating process, nickel and gold plated layers should be formed to thick thicknesses, incurring considerable cost. This cost problem encountered in the conventional process is needed to be solved.

The present inventors have conducted research aimed at improving the properties of underlying nickel plated layers to bring about cost reduction as well as to improve the physical properties of all plated layers. Conventional hard gold plating processes use direct current (DC). As an alternative, bipolar current may be used instead of DC. In this case, however, all rectifiers used in DC-based hard gold plating processes should be exchanged with new ones, which require an enormous investment cost for equipment replacement.

Not very much research has been conducted on nickel plated layers. Particularly, techniques for forming nickel plated layers with good characteristics without the need to exchange conventional DC-based equipment are not developed yet. Under these circumstances, there is a need to develop an alternative process by which gold plated layers can be reduced in thickness while maintaining their physical properties, without the need to substantially exchange existing equipment.

According to an embodiment of the present invention, a nickel-tungsten alloy plating solution is provided. The nickel-tungsten alloy plating solution includes a water-soluble nickel compound, a water-soluble tungsten compound, a complexing agent, and a ductility improver.

The functions and plating principle of the plating solution will be explained in brief.

Tungsten (W) plating can be explained by Reaction 1:

WO₄²⁻+4H₂O+6e⁻→W+8OH⁻ (1)

It is known that tungsten alone cannot be substantially plated due to its very low deposition potential and very high overvoltage for reduction. Many methods are used for alloy plating with tungsten. Particularly, tungsten tends to form a solid solution with a transition metal in a plating bath. The solid solution increases the deposition potential of tungsten and decreases the overvoltage for the reduction of tungsten, facilitating alloy plating with the transition metal and inducing the deposition of the alloy. This is called “induced alloy codeposition.” Many hypotheses have been proposed to explain the mechanism of induced alloy codeposition. Of these, the most reasonable hypothesis is known to be a deposition mechanism resulting from pH rise and solubility decrease at the cathodic interface.

The water-soluble nickel compound used in the nickel-tungsten alloy plating solution is selected from the group consisting of nickel sulfate salts (e.g., NiSO₄.H₂O), nickel sulfamate, and ammonium nickel sulfate. The water-soluble nickel compound is present in an amount of about 0.5 to about 10.0% by weight, preferably about 2.0 to about 4.0% by weight, based on the total weight of the plating solution. If the content of the water-soluble nickel compound is less than 0.5% by weight, the plating rate of the plating solution is considerably lowered, making it impossible to expect satisfactory productivity. Meanwhile, if the content of the water-soluble nickel compound exceeds 10.0% by weight, an optimal alloy plating ratio is not obtained, making it impossible to exhibit desired physical properties.

The water-soluble tungsten compound used in the nickel-tungsten alloy plating solution is most generally sodium tungstate. The water-soluble tungsten compound is present in an amount of about 3.0 to about 15.0% by weight, preferably about 9.0 to about 11.0% by weight, based on the total weight of the plating solution. The presence of the water-soluble tungsten compound in an amount of less than 3.0% by weight leads to a low tungsten content of a plated layer, which adversely affects the physical properties of the plated layer. Meanwhile, the addition of the water-soluble tungsten compound in an amount exceeding 15.0% by weight does not contribute to further improvement of physical properties, which is uneconomical.

The complexing agent plays a role in complexing the metal ions to maintain uniform physical properties of a plated layer. The complexing agent is selected from the group consisting of citric acid compounds, such as citric acid and sodium citrate, amines, such as glycine, triethanolamine and hexapropylamine, and mixtures thereof. The complexing agent is present in an amount of about 2.0 to about 13.0% by weight, preferably about 7.0 to about 11.0% by weight, based on the total weight of the plating solution. Below 2.0% by weight, the metal ions present in the plating solution adversely affect the alloy plating ratio. Meanwhile, the presence of the complexing agent in an amount of more than 13.0% by weight leads to low plating efficiency.

The ductility improver included in the plating solution serves to relieve the internal stress of a plated layer to prevent the formation of possible cracks in the plated layer during subsequent electroplating using DC.

A water-soluble sulfone compound may be used as the ductility improver. The water-soluble sulfone compound may be selected from the group consisting of sulfonamides, sulfonimides, sulfonic acid, sulfonates, and mixtures thereof. Specific examples of water-soluble sulfone compounds suitable for use in the plating solution may include allyl sulfonate, benzene sulfonamide, sodium vinyl sulfonate, and propane sulfonate. The ductility improver is present in an amount of about 0.01 to about 5.0% by weight, preferably about 0.1 to about 1.0% by weight, based on the total weight of the plating solution. Below 0.01% by weight, an influence on the internal stress of a plated layer is negligible, and as a result, the plated layer is apt to crack. Meanwhile, the addition of the ductility improver in an amount exceeding 5.0% by weight does not contribute to further improvement of physical properties, which is uneconomical.

The plating solution may further include additives, for example, a buffer, a primary brightener for plating rate control, a secondary brightener including a function of grain refinement, an anti-pit agent, and a surfactant.

The buffer functions to secure the stability of the solution in response to a steep change in pH. The buffer is selected from the group consisting of aqueous ammonia, boric acid, and a mixture thereof. The buffer is present in an amount of about 0.5 to about 10.0% by weight, preferably about 3.0 to about 5.0% by weight, based on the total weight of the plating solution. Below 0.5% by weight, stable physical properties of a plated layer are difficult to obtain because the pH of the plating solution greatly affects the physical properties of the plated layer, and the lifetime of the plating solution is shortened, which is a cause an increase in manufacturing cost. Above 10.0% by weight, the stability of the plating solution is improved but the plating rate of the plating solution is lowered.

The primary brightener serves to control the plating rate of the plating solution to ensure the uniformity of a plated layer. Examples of primary brighteners suitable for use in the plating solution include allylsulfonic acid, benzenesulfonic acid, benzoic acid, propionic acid, isopropyl alcohol, ethylene glycol, and glycerin. These primary brighteners may be used alone or as a mixture of two or more thereof. The primary brightener is present in an amount of about 0.01 to about 2% by weight, preferably about 0.1 to about 1% by weight, based on the weight of the plating solution. The presence of the primary brightener in an amount of less than 0.01% by weight has no significant influence on the control of plating rate, making it difficult to obtain a uniform plated layer. Meanwhile, the addition of the primary brightener in an amount exceeding 2% by weight does not contribute to further improvement of physical properties, which is economically disadvantageous.

The secondary brightener serves to cause refinement of the deposit grain, making a plated layer glossy and the texture dense. Examples of secondary brighteners suitable for use in the plating solution include propargyl alcohol, butynediol, gelatin, coumarin, diethyl-2-propen-1-amine, butene-1,4-diol-glycerol ether, and butanesulfonic acid. These secondary brighteners may be used alone or as a mixture of two or more thereof. The secondary brightener is present in an amount of about 0.0005 to about 0.01% by weight, preferably about 0.001 to about 0.005% by weight, based on the weight of the plating solution. The presence of the secondary brightener in an amount of less than 0.0005% by weight makes it difficult to expect refinement of the plating particles. Meanwhile, the presence of the secondary brightener in an amount of exceeding 0.01% by weight poses a risk that the physical properties of a plated layer may be adversely affected.

The anti-pit agent serves to ensure a smooth release of hydrogen gas during plating, leaving no fine pits on the surface of a plated layer. Examples of anti-pit agents suitable for use in the plating solution include ethylhexyl sulfate and naphthalene compounds. These anti-pit agents may be used alone or as a mixture of two or more thereof. The anti-pit agent is present in an amount of about 0.001 to about 1.0% by weight, preferably about 0.003 to about 0.05% by weight, based on the weight of the plating solution. If the content of the anti-pit agent is less than 0.001% by weight, it is difficult to expect the ability of the anti-pit agent to prevent the formation of pits. Meanwhile, if the content of the anti-pit agent exceeds 1.0% by weight, there is a risk that the plating rate may be lowered.

The surfactant is added to improve other properties (e.g., wettability) of the plating solution. Examples of surfactant suitable for use in the plating solution include polyoxyethylene lauryl ether, polyoxyethylene oleyl ether, polyoxyethylene cetyl ether, polyoxyethylene octyl ether and polyoxyethylene tridecyl ether, which are derived from polyoxyethylene glycol ether groups, and polyoxyethylene laurylamine ether and polyoxyethylene stearylamine ether, which are derived from polyoxyethylene alkyl amine ether groups. These surfactants may be used alone or as a mixture of two or more thereof. The surfactant may be present in an amount of about 0.001 to about 1.0% by weight, preferably about 0.005 to about 0.02% by weight, based on the total weight of the plating solution. The presence of the surfactant in an amount of less than 0.001% by weight makes it difficult to expect satisfactory wetting effects. Meanwhile, the presence of the surfactant in an amount exceeding 1.0% by weight increases the risk that the physical properties of a plated layer may be negatively affected.

According to an embodiment, a method for plating a printed circuit board with the plating solution is provided. The formation of a plated layer using the plating solution is as follows. FIG. 2 is a process flow chart illustrating a method for forming a nickel-tungsten alloy plated layer and a gold-containing plated layer on a printed circuit board. Referring to FIG. 2, a printed circuit board is dipped in an electrodeposition bath containing a nickel-tungsten alloy plating solution including a water-soluble nickel compound, a water-soluble tungsten compound, a complexing agent and a ductility improver (step S1).

In step S2, an electric current is applied between both electrodes disposed in the electrodeposition bath to form a nickel-tungsten alloy plated layer on the surface of the printed circuit board. The electrodeposition may be controlled by varying the potential (or voltage) or current (or current density) applied between the electrodes. In some embodiments, the plated layer may be electrodeposited by direct-current (DC) plating, pulsed current plating, reverse-pulse current plating, or a combination thereof. Preferably, a direct current is used for the electrodeposition of the plated layer so that conventional equipment using a DC rectifier for hard gold plating can be utilized.

The current density of a direct current for plating is from 5 to 30 ASD, preferably from 10 to 20 ASD. Below 5 ASD, the plating rate is lowered, resulting in a low alloy content. Above 30 ASD, the plated layer is not uniform and is apt to crack.

In an embodiment, the pH of the plating solution is adjusted to about 4 to about 7, preferably 4.5 to 6.5, and the temperature of the plating solution is adjusted to from about 45 to about 65° C., preferably 50 to 60° C., which is required during plating.

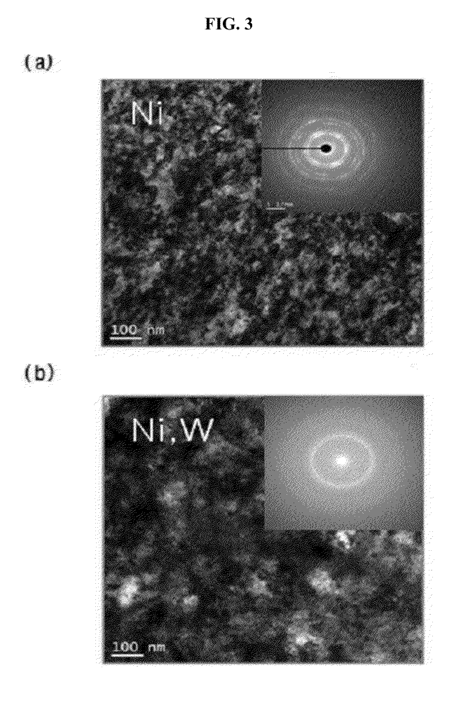

The crystal structures of an electroplated nickel-tungsten alloy layer formed using the plating solution and a conventional electroplated nickel layer for use in hard gold plating were compared and analyzed using a transmission electron microscope. FIG. 3 shows transmission electron microscopy images of the conventional electroplated nickel layer (a) and the electroplated nickel-tungsten alloy layer (b). The insets in the upper right hand corners of the figures show selected area electron diffraction (SAED) patterns. Referring to FIG. 3, it can be seen that much smaller nanocrystal grains were formed in the electroplated nickel-tungsten alloy layer than in the conventional hard gold plating.

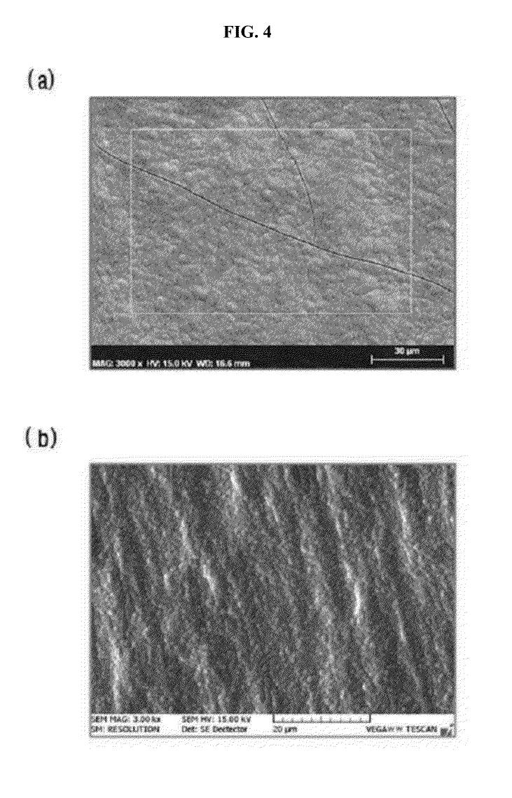

The plating solution according to an embodiment of the present invention, which includes the ductility improver, was plated using DC to form a plated layer. As a result, it can be confirmed that no cracks were formed in the plated layer. FIG. 4 shows the surface structures of plated layers formed using the plating solution with or without the ductility additive. Referring to FIG. 4, when a general nickel-tungsten alloy electroplating solution without the addition of the ductility improver was plated using DC, cracks were observed (see (a)). In contrast, when the plating solution including the ductility improver was plated using DC, no cracks were observed (see (b)).

In step S3, a gold-containing plated layer is formed on the nickel-tungsten alloy plated layer.

The gold-containing plated layer is formed to obtain satisfactory electrical properties while protecting the underlying nickel layer after the nickel-tungsten alloy electroplating. The gold-containing plated layer may be a hard gold plated layer or a gold-copper alloy plated layer. For example, the hard gold plated layer may be formed using a hard gold plating solution including potassium gold cyanide (PGC) as a major component, a complexing agent, a buffer, a brightener, surfactant, and a small amount of cobalt or nickel. The gold-copper alloy plated layer may be formed using a gold-copper alloy plating solution containing, for example, copper cyanide as an alloy source.

The gold-containing plated layer may be formed by various processes. An electroplating process using a direct current is preferred. By the formation of the gold-containing plated layer, the hardness and wear resistance of the plated portions of the printed circuit board can be greatly improved.

The thickness of the nickel-tungsten alloy plated layer is typically from about 1.0 to about 10 μm, preferably from about 2.5 to about 4.0 μm. The thickness of the nickel-tungsten alloy plated layer corresponds to half of that of a conventional electroplated nickel layer (generally at least 7 μm). The thickness of the gold-containing plated layer is typically from about 0.05 to about 3 μm, preferably from about 0.05 to about 0.7 μm, more preferably from about 0.15 to about 0.35 μm, whereas that of a conventional electroplated hard gold layer is from 0.76 to 3 μm. Even within this thickness range, sufficient physical properties can be exhibited. A practitioner skilled in the art can sufficiently understand that plated layers out of the thickness ranges defined above may also be formed by varying the processing conditions.

A brief explanation will be given of a procedure for plating a memory module as a representative product to which the present invention can be applied.

The plating process for the formation of the nickel-tungsten alloy plated layer required in the memory module is typically carried out for about 10 to about 20 minutes. The gold electroplating or gold alloy plating is generally performed for about 1 to about 5 minutes, which may be varied depending on the desired thickness thereof.

A pretreatment process may be optionally carried out before plating to optimize the formation of the nickel-tungsten plated layer and the gold-containing plated layer. Specifically, a terminal part and a connector part, which are made of copper, may be physically polished to remove impurities from the surfaces thereof before plating. Organic matter present on the surfaces of the terminal part and the connector part may also be chemically removed. Further, the copper layers are etched to a depth of about 1 μm using sulfuric acid and an oxidizing agent, followed by an acid rinse to remove oxide layers from the surfaces of portions to be plated before formation of the nickel-tungsten alloy electroplated layer. Finally, nickel-tungsten electroplating and gold electroplating are sequentially performed.

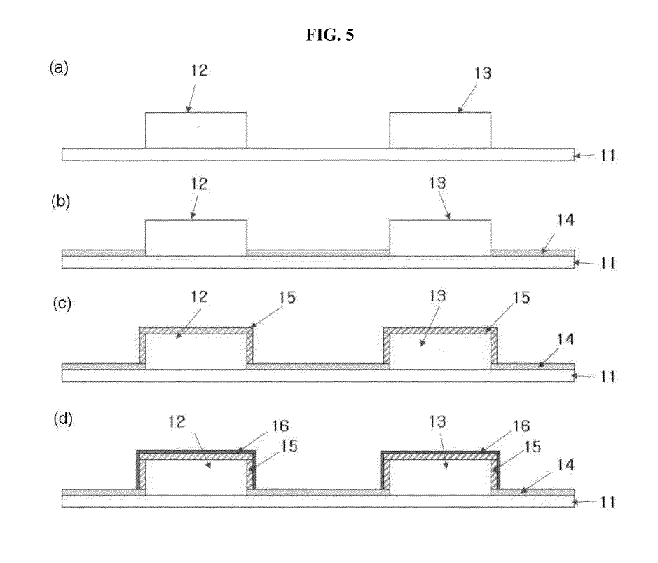

FIG. 5 schematically illustrates a process for plating the module product using the plating solution. Referring to FIG. 5, a circuit pattern (not shown), a pad part (not shown) on which components are mounted, a terminal part 12 for electrical connection to an external device, and a connector part 13 are formed on a substrate 11 ((a) in FIG. 5). This process is typically carried out by photolithography widely known in the art.

Then, a photoimageable solder resist (PSR) is applied to the portion other than the parts (the pad part, the terminal part and the connector part) to be plated to form a photoimageable solder resist layer 14 ((b) in FIG. 5). The photoimageable solder resist acts as a resist against the subsequent plating. Then, the pad part other than the terminal part and the connector part is masked with a dry film through light exposure and development because the pad part is surface treated for soldering by electroless plating and the terminal part and the connector part are electroplated in the subsequent step where high hardness and good wear resistance are required ((c) in FIG. 5). Thereafter, an electroplated nickel-tungsten alloy layer 15 and an electroplated gold or gold-copper alloy layer 16 are sequentially formed on the terminal part and the connector part by electroplating ((d) in FIG. 5).

After completion of the electroplating, the terminal part and the connector part are masked with dry films. The dry film applied to the pad part is stripped using a stripping solution containing caustic soda (NaOH) as a major component, and the surface of the pad part is plated for subsequent soldering. For the surface treatment, for example, an organic solderability preservative (OSP) may be applied to the surface of the pad part. Alternatively, the pad part may be subjected to electroless nickel-immersion gold plating.

The printed circuit board plated by the above method has a hardness of at least 300 Hv under a load of 10 gf, as measured using a micro-Vickers hardness tester, and a wear depth of 2.5 μm or less in a length of 2 mm under a load of 50 mN after 50 cycles, as measured using a wear resistance tester.

The electroplated nickel-tungsten layer and the gold plated layer included in the printed circuit board plated by the above method have satisfactory physical properties even at a small gold plating thickness due to their high hardness and good wear and corrosion resistance, thus bringing about remarkable cost reduction.

The present invention will be more clearly understood with reference to the following examples. These examples are given for illustrative purposes only and are not intended to limit the scope of the invention.

### EXAMPLES

### Examples 1-15

Memory modules, each of which had a size of 510×410 mm, a thickness of 1.0 mm±10 μm and a copper layer thickness of 20 μm±10 μm, were prepared. PSR was applied to the portion of each of the memory module other than a pad part, a terminal part and a connector part, which were made of copper. The memory module was degreased with 50-100 g/L sulfuric acid (SAC 161H, YMT Co., Ltd.) at 40° C. for 5 min and etched with 30 g/L sulfuric acid and 100 g/L Caroat. The copper layers were subjected to nickel-tungsten electroplating to form electroplated nickel-tungsten layers thereon, followed by hard gold electroplating to form gold plated or gold-copper alloy plated layers on the electroplated nickel-tungsten layers.

Nickel-tungsten electroplating solutions were prepared to have the compositions shown in Table 1. The degreased and etched memory modules were rinsed with water and dipped in and rinsed with a 5 wt % sulfuric solution for 1 min to form about 2 μm thick electroplated nickel-tungsten layers. The nickel-tungsten electroplating solutions had a temperature of 50° C. and a pH of 5.5. The nickel-tungsten electroplating was performed using DC with a current density of 10 ASD for 10 min. Thereafter, hard gold electroplating was performed on the nickel-tungsten alloy plated layers to form cobalt-containing gold plated layers (Examples 1-14). To investigate the characteristics of gold alloy plating, gold-copper alloy (75:25 (w/o)) plating was performed using DC to form a gold ally plated layer (Example 15). The physical properties of the gold alloy plated layer were compared with those of the cobalt-containing gold plated layers.

### Comparative Examples 1-2

Nickel-tungsten electroplating solutions were prepared to have the compositions shown in Table 1. Plating was performed using bipolar current under the same conditions, and the results were compared and analyzed. After nickel-tungsten plating, general hard gold electroplating (Comparative Example 1) and gold-copper alloy electroplating (Comparative Example 2) were performed separately, and the results were evaluated.

To evaluate the above plating solutions, conventional nickel electroplating and hard gold electroplating processes were performed to produce a reference specimen (see Remarks).

TABLE 1
Nickel-tungsten alloy electroplating solution compositions and plating conditions

| | | | Examples | | | | | | | | | |
|---|---|---|---|---|---|---|---|---|---|---|---|---|
| | | | Bath Composition No. | | | | | | | | | |
| Solution | Composition | Component | 1 | 2 | 3 | 4 | 5 | 6 | 7 | 8 | 9 | 10 |
| Nickel- | Nickel | Nickel | 30 | 30 | 30 | 30 | 30 | 30 | 30 | 30 | 30 | 30 |
| tungsten | compound | sulfate | | | | | | | | | | |
| alloy | Tungsten | Sodium | 100 | 100 | 100 | 100 | 100 | 100 | 100 | 100 | 100 | 100 |
| electro- | salt | tungstate | | | | | | | | | | |
| plating | Complexing | Citric | 90 | 90 | 90 | 90 | 90 | 90 | 90 | 90 | 90 | 90 |
| solution | agent | acid, glycine | | | | | | | | | | |
| | Buffer | Boric acid | 50 | 50 | 50 | 50 | 50 | 50 | 50 | 50 | 50 | 50 |
| | Ductility | Sulfonic | 0.5 | | | 0.5 | | | 0.5 | | | 0.5 |
| | improver | acid salt | | 3 | | | 3 | | | 3 | | |
| | | | | | 11 | | | 11 | | | 11 | |
| | Brighteners | Isopropyl | 0.1 | 0.1 | 0.1 | | | | 0.1 | 0.1 | 0.1 | 0.3 |
| | | alcohol | | | | | | | | | | |
| | | Propargyl | 0.1 | 0.1 | 0.1 | 0.1 | 0.1 | 0.1 | | | | 0.3 |
| | | alcohol | | | | | | | | | | |
| | | Glycerin | | | | 0.1 | 0.1 | 0.1 | 0.1 | 0.1 | 0.1 | |
| | Surfactant | | 0.2 | 0.2 | 0.2 | 0.2 | 0.2 | 0.2 | 0.2 | 0.2 | 0.2 | 0.2 |
| Gold | Hard (cobalt- | Potassium | 0 | 0 | 0 | 0 | 0 | 0 | 0 | 0 | 0 | 0 |
| electro- | containing) | gold cyanide, | | | | | | | | | | |
| plating | gold plating | cobalt sulfate, | | | | | | | | | | |
| solution | | etc. | | | | | | | | | | |
| | Gold alloy | Potassium | | | | | | | | | | |
| | plating | gold cyanide, | | | | | | | | | | |
| | (gold-copper) | Potassium | | | | | | | | | | |
| | | copper cyanide, | | | | | | | | | | |
| | | etc. | | | | | | | | | | |
| Working | DC | | 0 | 0 | 0 | 0 | 0 | 0 | 0 | 0 | 0 | 0 |
| conditions | Reverse pulse | | | | | | | | | | | |
| | Plating time | | 10 | 10 | 10 | 10 | 10 | 10 | 10 | 10 | 10 | 10 |
| | (min) | | | | | | | | | | | |

| | | | Examples | | | | | Comparative | | |
|---|---|---|---|---|---|---|---|---|---|---|
| | | | Bath Composition No. | | | | | Examples | | |
| Solution | Composition | Component | 11 | 12 | 13 | 14 | 15 | 1 | 2 | Remarks |
| Nickel- | Nickel | Nickel | 30 | 30 | 30 | 30 | 30 | 30 | 30 | Conventional |
| tungsten | compound | sulfate | | | | | | | | nickel |
| alloy | Tungsten | Sodium | 100 | 100 | 100 | 100 | 100 | 100 | 100 | electro- |
| electro- | salt | tungstate | | | | | | | | plating |
| plating | Complexing | Citric | 90 | 90 | 90 | 90 | 90 | 90 | 90 | |
| solution | agent | acid, glycine | | | | | | | | |
| | Buffer | Boric acid | 50 | 50 | 50 | 50 | 50 | 50 | 50 | |
| | Ductility | Sulfonic | | | | | | | | |
| | improver | acid salt | 3 | | 3 | 3 | 3 | 3 | 3 | |
| | | | | 11 | | | | | | |
| | Brighteners | Isopropyl | 0.3 | 0.3 | 0.1 | 0.1 | 0.1 | 0.1 | 0.1 | |
| | | alcohol | | | | | | | | |
| | | Propargyl | 0.3 | 0.3 | 0.1 | 0.1 | 0.1 | 0.1 | 0.1 | |
| | | alcohol | | | | | | | | |
| | | Glycerin | | | | | | | | |
| | Surfactant | | 0.2 | 0.2 | 0.2 | 0.2 | 0.2 | 0.2 | 0.2 | |
| Gold | Hard (cobalt- | Potassium | 0 | 0 | 0 | 0 | | 0 | | Conventional |
| electro- | containing) | gold cyanide, | | | | | | | | hard gold |
| plating | gold plating | cobalt sulfate, | | | | | | | | plating |
| solution | | etc. | | | | | | | | |
| | Gold alloy | Potassium | | | | | 0 | | 0 | |
| | plating | gold cyanide, | | | | | | | | |
| | (gold-copper) | Potassium | | | | | | | | |
| | | copper cyanide, | | | | | | | | |
| | | etc. | | | | | | | | |
| Working | DC | | 0 | 0 | 0 | 0 | 0 | | | 0 |
| conditions | Reverse pulse | | | | | | | 0 | 0 | |
| | Plating time | | 10 | 10 | 15 | 20 | 10 | 10 | 10 | |
| | (min) | | | | | | | | | |

In accordance with the same procedures and conditions as described above, nickel-tungsten alloy plated layers were formed, followed by gold electroplating. The plated specimens were measured for plating thickness, hardness, wear resistance and corrosion resistance (porosity) by the following conditions and methods. The results are shown in Table 2.

<Plating Thickness Measurement>

The plating thicknesses of the specimens were measured using a FIB system.
FIB system
Maker: FEI
Model: NOVA-600

<Hardness Measurement>

Hardness is the most important property required in the applied products. The hardness values of the specimens were measured using a micro-Vickers hardness tester.
Micro-Vickers hardness tester
Maker: Shimadzu
Model: HMV-2
Load: 10 gf

<Wear Resistance Measurement>

Wear resistance, together with hardness, is another important property. The wear depths of the specimens after testing were measured using a wear resistance tester to evaluate the wear resistance thereof
Wear resistance tester
Maker: Innowep
Model: UST-1000
Length: 2 mm
Load: 50 mN
Number of cycles: 50

<Porosity Measurement>

24 hr after the plated specimens were placed in a nitric acid gas atmosphere, an observation was made as to whether corrosion occurred. Specifically, a 60% nitric acid (HNO₃) was put into desiccators, and then the specimens were allowed to stand in the corresponding desiccators in a sealed state at room temperature for 24 hr. The specimens were taken out of the desiccators and were observed under a microscope as to whether the terminal parts were corroded.

TABLE 2
Evaluation results of properties

| | | Examples | | | | | | | | | |
|---|---|---|---|---|---|---|---|---|---|---|---|
| | Plating | Bath Composition No. | | | | | | | | | |
| Properties | composition | 1 | 2 | 3 | 4 | 5 | 6 | 7 | 8 | 9 | 10 |
| Plating | Nickel- | 2.03 | 2.09 | 2.04 | 2.13 | 2.06 | 2.10 | 2.10 | 2.06 | 2.03 | 1.96 |
| thickness(μm) | tungsten | | | | | | | | | | |
| | Gold | 0.15 | 0.16 | 0.15 | 0.15 | 0.16 | 0.16 | 0.15 | 0.16 | 0.15 | 0.15 |
| Hardness | | 331 | 336 | 335 | 329 | 333 | 342 | 339 | 344 | 340 | 332 |
| (Hv) | | | | | | | | | | | |
| Wear | | 2.18 | 2.15 | 2.16 | 2.22 | 2.20 | 2.19 | 2.31 | 2.15 | 2.26 | 2.11 |
| resistance | | | | | | | | | | | |
| (μm) | | | | | | | | | | | |
| Corrosion | | ◯ | ⊚ | ◯ | Δ | ◯ | ◯ | ◯ | ⊚ | ◯ | ◯ |
| resistance | | | | | | | | | | | |

| | | Examples | | | | | Comparative | | |
|---|---|---|---|---|---|---|---|---|---|
| | Plating | Bath Composition No. | | | | | Examples | | |
| Properties | composition | 11 | 12 | 13 | 14 | 15 | 1 | 2 | Remarks |
| Plating | Nickel- | 2.03 | 2.05 | 3.97 | 8.025 | 2.10 | 2.09 | 2.13 | 7.21 |
| thickness(μm) | tungsten | | | | | | | | (nickel) |
| | Gold | 0.16 | 0.15 | 0.16 | 0.15 | 0.16 | 0.16 | 0.15 | 1.06 |
| Hardness | | 335 | 336 | 436 | 634 | 345 | 348 | 340 | 203 |
| (Hv) | | | | | | | | | |
| Wear | | 2.16 | 2.18 | 1.98 | 1.55 | 2.09 | 2.08 | 2.12 | 2.97 |
| resistance | | | | | | | | | |
| (μm) | | | | | | | | | |
| Corrosion | | ⊚ | ◯ | ⊚ | ⊚ | ⊚ | ⊚ | ⊚ | X |
| resistance | | | | | | | | | |

⊚: Excellent
◯: Good
Δ: Average
X: poor

From the test results in Table 2, it can be seen that the electroplated nickel-tungsten alloy layers and the hard gold plated layers or the gold-copper alloy plated layers formed in Examples 1-15 all showed satisfactory results in terms of the above-mentioned physical properties.

As is apparent from the foregoing, according to the plating method of the present invention, all plating properties required in terminal parts and connector parts of electronic components, such as memory modules and battery terminals, are met and the thickness of plated layers can be reduced to half or less of that of hard gold plated layers formed by conventional plating processes. Therefore, the method of the present invention can advantageously shorten the processing time and contribute to productivity improvement and drastic cost reduction.

In addition, the method of the present invention can use conventional DC rectifiers without the need for replacement, enabling plating of printed circuit boards without the need to repair and replace conventional equipment. Therefore, initial investment costs for equipment can be greatly reduced.

Simple modifications and changes of the present invention belong to the scope of the present invention. Thus, the specific scope of the present invention will be clearly defined by the appended claims.

1-4. (canceled)

5. A plating method for printed circuit board, the method comprising:
dipping a printed circuit board in an electrodeposition bath containing a nickel-tungsten alloy plating solution comprising a water-soluble nickel compound, a water-soluble tungsten compound, a complexing agent, and a ductility improver;
applying an electric current between both electrodes disposed in the electrodeposition bath to form a nickel-tungsten alloy plated layer on the surface of the printed circuit board; and
forming a gold-containing plated layer on the nickel-tungsten alloy plated layer.

6. The method according to claim 5, wherein the gold-containing plated layer is a hard gold plated layer or a gold-copper alloy plated layer.

7. The method according to claim 5, wherein the electric current is a direct current.

8. The method according to claim 7, wherein the direct current has a current density of 5 to 30 ASD.

9. The method according to claim 5, wherein the plating solution has a pH 4 to 7 and a temperature of 45 to 65° C.

10. A method for plating a printed circuit board, the method comprising:
providing a printed circuit board comprising a circuit pattern, a pad part on which components are mounted, a terminal part for electrical connection to an external device, and a connector part;
masking the portion of the printed circuit board other than the terminal part and the connector part;
dipping the printed circuit board in a nickel-tungsten alloy plating solution comprising a water-soluble nickel compound, a water-soluble tungsten compound, a complexing agent, and a ductility improver;
forming a nickel-tungsten alloy plated layer on each of the exposed portions of the terminal part and the connector part by direct-current (DC) electroplating; and
forming a gold-containing plated layer on the nickel-tungsten alloy plated layer by DC electroplating.

11. A printed circuit board plated by the method according to claim 10.

12. The printed circuit board according to claim 11, wherein the nickel-tungsten alloy plated layer has a thickness of 1.0 to 10 μm.

13. The printed circuit board according to claim 11, wherein the gold-containing plated layer has a thickness of 0.05 to 3 μm.

14. The printed circuit board according to claim 11, wherein the gold-containing plated layer has a thickness of 0.05 to 0.7 μm.

15. The printed circuit board according to claim 11, wherein the printed circuit board has a hardness of at least 300 Hv under a load of 10 gf, as measured using a micro-Vickers hardness tester, and a wear depth of 2.5 μm or less in a length of 2 mm under a load of 50 mN after 50 cycles, as measured using a wear resistance tester.
